(19) United States
(12) Patent Application Publication
(10) Pub. No.: US 2004/0183552 A1
(43) Pub. Date: Sep. 23, 2004

(54) Fuel measuring cell

(76) Inventors: Hossein Aghamehdi, York, PA (US); Jack Burwick, York, PA (US); Yong Shin, York, PA (US)

Correspondence Address: William H. McNeill, OSRAM SYLVANIA Inc., 100 Endicott Street, Danvers, MA, 01923, US

(21) Appl. No.: 10/796,393

(22) Filed: Mar. 9, 2004

Related U.S. Application Data
(60) Provisional application No. 60/456,844, filed on Mar. 21, 2003.

(51) Int. Cl. F02B 1/00; G01R 27/26

(52) U.S. Cl. 324/690

(57) ABSTRACT

A single cell fuel sensor (10) has a housing (12) including a fuel inlet chamber (14), a fuel mixing chamber (16) and a fuel outlet chamber (18). The fuel inlet chamber (14) includes an inlet orifice (20) leading into the mining chamber (16) at a given level and the fuel outlet chamber (18) includes an outlet orifice (22) leading out of the mixing chamber (16) at a second level that is spaced from the given level. An electrode (24) is fitted into the mixing chamber and electrically isolated from the housing (12), for example by a glass seal (26). In a preferred embodiment of the invention the housing (12) is an insert casting.

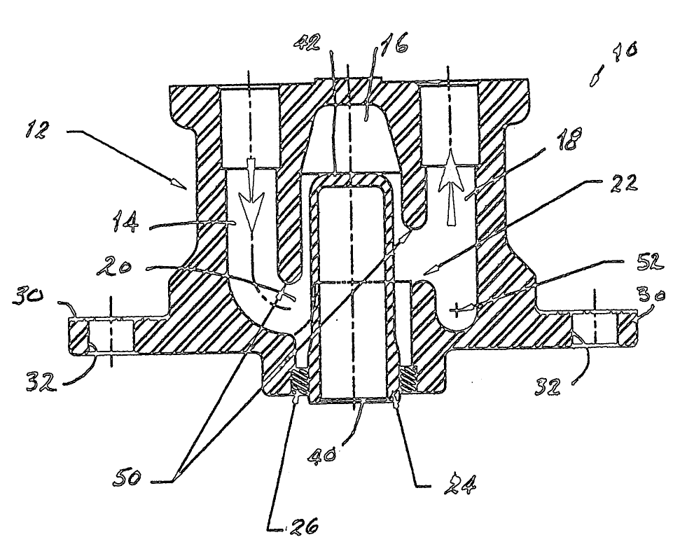

### CROSS-REFERENCE TO RELATED APPLICATIONS

This application claims priority from Provisional Application No. 60/456,844, Sled Mar. 21, 2003.

### TECHNICAL FIELD

This invention relates to fuel measuring cells and more particularly to a single cell fuel sensor.

### BACKGROUND ART

Fuel measuring cells generally employ two chambers to generate an electrical measurement of the fuel that resides inside the measuring cell at point in time. The interior of these cells is essentially symmetrical in design. Such cells are used, for example, for measuring the mixture of ethanol and methanol in engines, using such a mixture, The cell generates a variable signal that is sent to the engine control module and is based upon the capacitance of the fuel mixture being processed, as measured across certain volumetric gaps inside the cell

Such cells are complicated and expensive to produce, usually employing machined parts and complicated designs.

### DISCLOSURE OF INVENTION

It is, therefore, an object of the invention to obviate the disadvantages of the prior art.

It is another object of the invention to enhance fuel measuring cells.

These objects are accomplished, in one aspect of the invention by the provision of a single cell fuel sensor comprising a housing including a fuel inlet chamber, a fuel mixing chamber and a fuel outlet chamber. The fuel inlet chamber includes an inlet orifice leading into the mixing chamber at a given level and the fuel outlet chamber includes an outlet orifice leading out of the mixing chamber at a second level that is spaced from the given level. An electrode is fitted into the mixing chamber, and electrically isolated from the housing.

Since the inlet orifice and outlet orifice are at different levels, an asymmetric inlet and outlet orifice arrangement is produced which provides greater fuel mixing and insures that the flow of electrolyte (mixed fuel) fills the electrode area before the fuel is discharged through the outlet orifice. This off-set feature also assures the electrolyte (mixed fuel) contacts and wets the maximum possible surface area of the electrode.

### BRIEF DESCRIPTION OF THE DRAWINGS

The single FIGURE is a cross-sectional elevational view of an embodiment of the invention.

### BEST MODE FOR CARRYING OUT THE INVENTION

For a better understanding of the present invention, together with other and further objects, advantages and capabilities thereof reference is made to the following disclosure and appended claims in conjunction with the above-described drawings.

Referring now to the single FIGURE with greater particularity, there is shown a single cell fuel sensor 10 comprising a housing 12 including a fuel inlet chamber 14, a fuel mixing chamber 16 and a fuel outlet chamber 18. The fuel inlet chamber includes an inlet orifice 20 leading into the mixing chamber 16 at a given level and the fuel outlet chamber 18 includes an outlet orifice 22 leading out of the mixing chamber 16 at a second level that is spaced from the given level. An electrode 24 is fitted into the mixing chamber and electrically isolated from the housing 12, for example by a glass seal 26. In a preferred embodiment of the invention the housing 12 is an insert casting.

The housing 12 is provided with extending ears 30 provided with mounting apertures 32 to ease assembly to associated parts.

The electrode 24 is cup-shaped in the preferred embodiment, that is, it is essentially tubular with an open end 40 and a closed bottom 42. To insure good fuel flow into and out of the Ming chamber 16 the inlet and outlet orifices 20, 22 are provided with rounded corners, as shown at 50.

A depression 52 formed at the bottom of the outlet chamber 18 promotes the desired fluid turbulence inside the cell.

There is thus provided a single cell fuel sensor that is simple in construction and yet allows non-laminar flow inside the cell, providing for greater sensitivity to subtle changes in the fuel mixture, By locating the inlet and outlet orifices at different levels extensive exposure of the fuel mixture to the interior surfaces of the mixing chamber is ensured.

While there have been shown and described what are at present considered to be the preferred embodiments of the invention, it will be apparent to those skilled in the art that various changes and modification can be made herein without departing from the scope of the invention as defined by the appended claims.

What is claimed is:

1. A single cell fuel sensor comprising:
a housing including a fuel inlet chamber, a fuel mixing chamber and a fuel outlet chamber;
said fuel inlet chamber including an inlet orifice leading into said mixing chamber at a given level;
said fuel outlet chamber including an outlet orifice leading out of said mixing chamber at a second level, spaced from said given level; and
an electrode fitted into said mixing chamber, said electrode being electrically isolated from said housing.

2. The single cell fuel sensor of claim 1 wherein said electrical isolation is accomplished by a glass seal between said housing and said electrode.

3. The single cell fuel sensor of claim 1 said housing is provided with extending ears provided with mounting apertures.

4. The single cell sensor of claim 1 wherein said electrode is cup-shaped.

5. The single cell sensor of claim 1 wherein said inlet and said outlet orifices are provided with rounded corners.
